(19) United States
(12) Patent Application Publication
(10) Pub. No.: US 2010/0019865 A1
(43) Pub. Date: Jan. 28, 2010

(54) Module With Frequency-Tunable Function

(76) Inventors: Francois Baron, Thorigne-Fouillard (FR); Corinne Nicolas, La Chapelle Des Fougeretz (FR); Dominique Lo Hine Tong, Rennes (FR)

Correspondence Address: Robert D. Shedd, Patent Operations;THOMSON Licensing LLC, P.O. Box 5312, Princeton, NJ, 08543-5312, US

(21) Appl. No.: 12/086,945

(22) PCT Filed: Nov. 29, 2006
(86) PCT No.: PCT/EP2006/069069

§ 371 Date: Sep. 23, 2009

(30) Foreign Application Priority Data
Dec. 22, 2005 (FR) 05 13122

(51) Int. Cl. H03H 9/17

(52) U.S. Cl. 333/188

(57) ABSTRACT

The invention relates to an electronic package comprising a substrate, a frequency tunable function at the surface of the said substrate, a dielectric material having variable permittivity with an electrical excitation in contact with the said function and a support secured to the substrate so as to define the package, characterized in that the substrate comprises a membrane, the said membrane lying between an upper cavity and a lower cavity of the package, at least one cavity being filled with the dielectric material that can be a liquid crystal. The presence of two cavities, at least one of which is filled with variable-permittivity dielectric material, makes it possible to increase the operating frequency range of the function.

The field of the invention is that of electronic components, integrated into micro-machined structures, and that are particularly beneficial especially for microwave component applications for which low losses are required.

Micro-machining technology allows the making of active or passive structures whose dimensions and weight are greatly reduced with respect to the more conventional technologies, such as printed circuits, while decreasing the cost and appreciably improving performance at millimetric frequencies. In particular, the ability of this technique to integrate functionalities in 3 dimensions makes it possible to increase the integration density of the circuits. It also offers the possibility of integrating, in the very interior of these micro-machined structures, high-level multi-function systems in a single planar technology. For example, the integration of active components by flip-chip or wiring is quite conceivable with this type of technology.

It also makes it possible to easily integrate micro-machined passive components as a replacement for discrete components, which often demand complex and consequently expensive integration studies. Moreover, this technology has the advantage of allowing the direct integration of MEMS (Micro Electronic Memory System) components and of obtaining very efficacious systems from 1 GHz to a few THz, while reducing the dimensions of the final structures.

Micro-machined circuits do not require any particular encapsulation, that is to say they do not need any external packages or supports, since the protection of the circuits is achieved naturally by the shielding of the structures.

Micro-machining technology makes it possible to etch conductors on a very fine membrane (about 10 μm) and to encapsulate the whole of the structure in a solid substrate. It can be applied to any type of semi-conductor substrate, but the use of silicon makes it possible to decrease the manufacturing costs more appreciably, this substrate being widely employed in the semi-conductor industry.

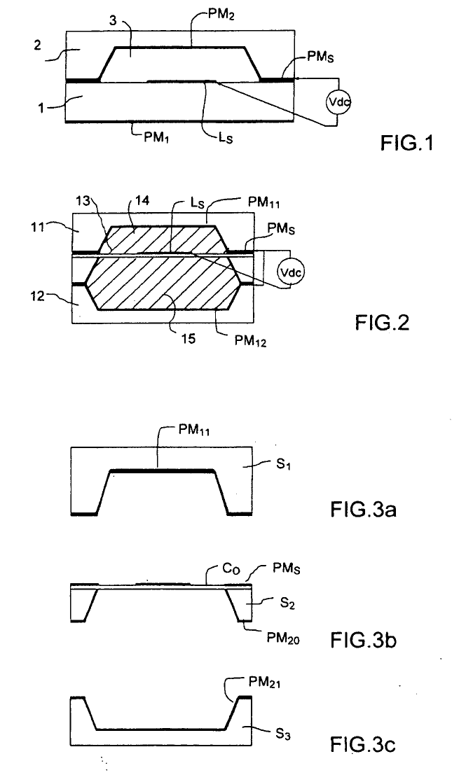

Modules comprising micro-machined structures comprising frequency tunable functions such as that illustrated in FIG. 1 have in particular already been proposed. An etched signal line L_{S} and an associated ground plane PM_{S} are defined at the surface of a substrate 1 and encapsulated in a micro-machined structure defined by the substrate and a support 2, typically obtained by machining a silicon piece. This involves a so-called triplate structure defined by three levels of ground plane: PM₁, PM_{S} and PM₂, the ground planes PM₁ and PM₂ ensuring the electromagnetic shielding of the whole, comprising a cavity 3.

Additionally, it is known to be able to achieve frequency tunable functions by using dielectric materials whose characteristics vary with an electrical excitation.

For example, the use of liquid crystals making it possible to achieve variable capacitors or phase shifters, but also tunable filters, has been described in the literature (“Tunable Passive Phase Shifter for Microwave Applications using Highly isotropic Liquid Crystals”, WEIF-32, IEEE MTT-S Digest 2004, pp 1153-1156, “Ferro-electric and Liquid Crystal Tunable Microwave Phase Shifters”, 33rd European Microwave Conference—Munich 2003, pp 1431-1434, “Improvement of an Inverted Microstrip Line-Based Microwave Tunable Phase-Shifter using Liquid Crystal”, 33rd European Microwave Conference—Munich 2003, pp 1417-1420, “Nouvelles structures de déphaseurs agiles en fréquence à substrat cristal liquide” [New frequency-agile phase shifter structures with liquid crystal substrate], 12th Journées Nationales Microondes, 16-17-18 May 2001—POITIERS, 6B1).

To render the function defined by the signal line and its ground plane frequency tunable, it has already been proposed to fill the cavity 3 with a material, for example, of liquid crystal type whose permittivity can be controlled electrically.

Nevertheless, the presence of the ground-like substrate represents a drawback in this type of structure, on the one hand because of the high permittivity of the materials conventionally employed as substrate and on the other hand through the non-frequency tunability of their dielectric properties.

In this context, the present invention proposes a novel electronic package comprising a substrate, a frequency tunable function, a dielectric material having variable permittivity with an electrical excitation in contact with the said function and a support secured to the substrate so as to define the package, characterized in that the substrate comprises a membrane supporting the tunable function, the said membrane lying between an upper cavity and a lower cavity of the package, at least one cavity being filled with the dielectric material.

Advantageously, the variable-permittivity dielectric material can comprise a liquid crystal. This may be a homogeneous material or a composite material comprising a polymer and liquid crystal dispersed in the polymer.

Advantageously, the substrate comprises a first part made of semiconductor material exhibiting a locally machined surface, a second part comprising a membrane supported by a semiconductor material comprising a locally machined surface, the said first part and second part being assembled, the machined surfaces being opposite one another, the lower cavity being defined between these machined surfaces and the membrane.

Advantageously, the support comprises a third locally machined part made of semiconductor material, the upper cavity being defined between the said machined surface and the membrane.

Advantageously, one or both cavities are filled with at least one material comprising liquid crystal.

Advantageously, the function can be of filter, delay line, phase shifter, etc. type.

Advantageously, the function comprises a signal line and an associated ground plane.

Advantageously, the lower face of the upper cavity and the upper face of the lower cavity each comprise a ground plane for the signal, making it possible to ensure the electromagnetic shielding of the package in relation to the frequency tunable function. It should be noted that the concept of ground plane in the present case relates to the frequency band of the useful signal, the ground for the DC voltages possibly being different.

Advantageously, the machined surfaces of the semiconductor substrates are metallized to constitute ground planes.

According to a variant of the invention, the means for frequency tuning the function consist of an electric field applied either between the structure etched on the membrane on the one hand and at least one of the ground planes on the other hand, or between the two ground planes which in this case are isolated from a DC signal point of view.

Advantageously, the package may be made of silicon, the membrane being made of material of silica or silicon nitride type or a combination of the two, or else of benzocyclobutene.

Advantageously, the function and/or the ground planes are made of metal. This can in particular be gold.

The subject of invention is also a method of manufacturing an electronic package according to the invention furthermore comprising the following steps:
making a first locally machined substrate
making a membrane comprising a frequency tunable function, supported by a second locally machined substrate
making a third locally machined substrate
assembling the three substrates so as to define a package comprising a lower cavity and an upper cavity on either side of the membrane.
filling at least one cavity with a fluid material comprising a dielectric material having variable permittivity with an electrical excitation.

Advantageously, the dielectric material can comprise liquid crystal.

According to a variant of the invention, the filling of material comprising liquid crystal is performed by injection.

According to a variant of the invention, the machined surfaces of the first, second and third substrates are metallized.

Advantageously the substrates are made of silicon.

According to an alternative method according to the invention, the substrates can be machined by photolithography.

The invention will be better understood and other advantages will become apparent on reading the nonlimiting description which follows and by virtue of the appended figures among which:

FIG. 1 illustrates an exemplary electronic package comprising a frequency tunable function according to the known art

FIG. 2 illustrates an exemplary package of the invention, comprising two cavities delimited by a membrane

FIGS. 3a to 3c illustrate the steps of a method of manufacturing the package according to the invention

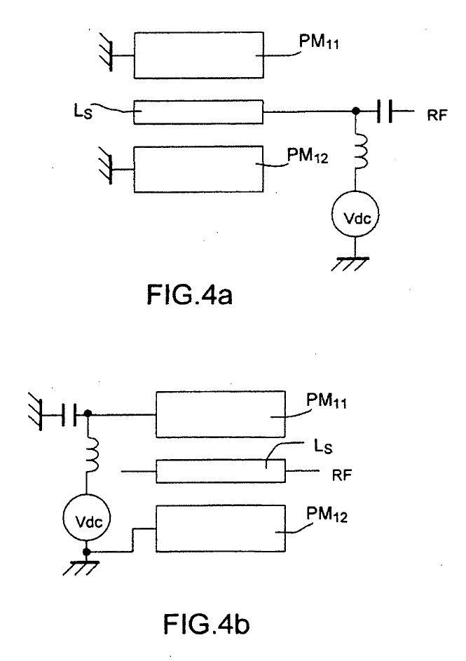

FIGS. 4a and 4b illustrate two examples of addressing the frequency tunable function

FIG. 5 illustrates an exemplary 3-pole filter made at the surface of the membrane in a package according to the invention

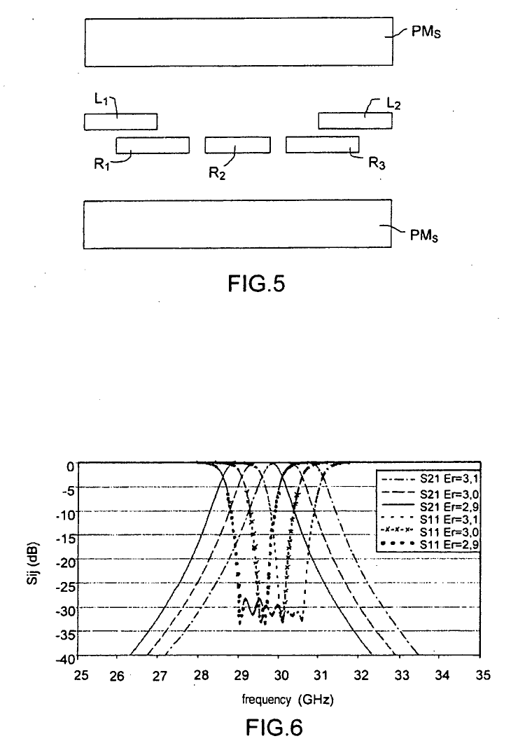

FIG. 6 illustrates the evolutions of the matching and of the transmission as a function of frequency for various permittivity values adjusted by modifying the DC voltage applied to a liquid crystal used in a package according to the invention.

The electronic package proposed in the present invention comprises in a general manner two cavities delimited by a membrane on which is made at least one component, also called a function, that one seeks to render frequency tunable, as illustrated in FIG. 2 which represents a view in section of an exemplary package according to the invention.

More precisely the package is defined by a first part or support 11 and a second part 12 also called the substrate, separated by a membrane 13 on which the function, in the case represented a micro-strip line L_{S}, is made. Two cavities, upper 14 and lower 15, are thus defined on either side of the membrane 13. At least one of these two cavities is filled with dielectric material having frequency tunable permittivity, advantageously both may be so, as represented in the present case by hatching relating to the dielectric material. Additionally, the structure thus made comprises three levels of ground plane: PM_{S}, PM₁₁ and PM₁₂.

Example of Making a Package Comprising Cavities made in Silicon Substrates:

We shall describe in greater detail the making of the package from several silicon substrates:
A first silicon substrate S₁ is used, on which a mask is made by photolithography so as to be able to define a zone intended for etching. After etching, the whole of the surface is metallized and the machined substrate such as represented in FIG. 3a and comprising the ground plane PM₁₁, is obtained
A second substrate S₂ is used, corresponding to a silicon substrate covered with an oxide layer on the upper face, as represented in FIG. 3b. In place of oxide, other materials can be used as mentioned above for the membrane. This piece is machined on the lower face until etching stops on the oxide layer, thus forming the membrane intended to receive the tunable function. On the oxide layer Co, on the upper face, a micro-strip line L_{S} is therefore deposited which is intended to constitute the frequency tunable function, as well as an associated ground plane PM_{S}, and on the rear face another metallization PM₂₀
A third silicon substrate S₃ machined and covered with a metallic layer illustrated in FIG. 3c is used to make a substrate similar to that illustrated in FIG. 3a and comprising the ground plane PM₂₁
The three substrates S₁, S₂ and S₃ are then assembled by brazing, adhesive bonding or thermo-compression. The package is thus defined together with its two cavities and its ground planes allowing shielding: PM₁₁ and PM₁₂ defined by the metallizations PM₂₀ and PM₂₁.

Having made the package integrating the two cavities, the filling with a fluid liquid crystal material is carried out. This filling operation can be performed by injection using openings made in the cover and which allow the passage of the hyper-frequency ports, so as to connect the frequency tunable function.

The voltage control of the liquid crystal can be done in various ways. FIGS. 4a and 4b illustrate possible electrical layouts. Thus FIG. 4a illustrates a configuration in which an RF radio-frequency voltage and a DC voltage Vdc are applied to the structure etched on the membrane at the level of the micro-strip line L_{S}.

FIG. 4b illustrates another possible configuration in which the DC control voltage of the liquid crystal is applied between the ground plane elements PM₁₁ and PM₁₂ surrounding the micro-strip line.

Example of Making a Package According to the Invention Comprising a 3-pole Filter and Two Cavities Filled with Liquid Crystal

In the example chosen, the function is a 3-pole filter such as illustrated in FIG. 5 which illustrates a view from above depicting the constituent metallizations of the input line L₁ and output line L₂, of the resonators R₁, R₂ and R₃, of the associated signal ground planes PM_{S}. Other functions such as delay lines, phase shifters or the like can also be made.

The cavities are filled with the commercial nematic liquid crystal K15 from the company Merck whose relative permittivity can vary between 2.9 and 3.1.

The performance illustrated in FIG. 6 is obtained, corresponding to the evolution of the matching (descending curves) and of the transmission (ascending curves) as a function of operating frequency for various permittivities. The permittivity is adjusted by modifying the DC voltage applied.

The relative variation of the central frequency obtained is equal to \sqrt{εᵣ₂/εᵣ₁} i.e. here 1 GHz to 30 GHz. And as shown by the curves of FIG. 6, the matching level, around −30 dB, is fully preserved.

The performance in terms of amplitude of variation in operating frequency of the 3-pole filter in a package according to the known art and according to the invention have been compared.
a) Package with a prior art structure such as illustrated in FIG. 1 comprising an alumina substrate and a cavity filled with the liquid crystal K15:
Relative variation in the central frequency: 0.7%
b) Package with a prior art structure such as illustrated in FIG. 1 comprising a substrate made of RO 4003 polymer material and a cavity filled with the liquid crystal K15:
Relative variation in the central frequency: 1.6%
c) Package with a structure of the invention such as illustrated in FIG. 2 comprising a cavity filled with air and a cavity filled with the liquid crystal K15:
Relative variation in the central frequency: 3%
d) Package with a structure of the invention such as illustrated in FIG. 2 comprising two cavities filled with the liquid crystal K15:
Relative variation in the central frequency: 3.3%

1. Electronic package comprising a substrate, a frequency tunable function at the surface of the said substrate, a dielectric material having variable permittivity with an electrical excitation in contact with the said function and a support secured to the substrate so as to define the package wherein the substrate comprises a membrane supporting the tunable function, the said membrane lying between an upper cavity and a lower cavity of the package, at least one cavity being filled with the dielectric material.

2. Electronic package according to claim 1, wherein at least one cavity is filled with a material comprising liquid crystal.

3. Electronic package according to claim 2, wherein the material is a composite material comprising a polymer and liquid crystal.

4. Electronic package according to claim 1, wherein the lower face of the upper cavity and the upper face of the lower cavity each comprise a ground plane.

5. Electronic package according to claim 1, wherein the function comprises a micro-strip line and an associated ground plane.

6. Electronic package according to claim 5, wherein the substrate comprises a first part made of semiconductor material exhibiting a locally machined surface, a second part comprising a membrane supported by a semiconductor material comprising a locally machined surface, the said first part and second part being assembled, the machined surfaces being opposite one another, the lower cavity being defined between these machined surfaces and the membrane.

7. Electronic package according to claim 6, wherein the support comprises a machined part made of semiconductor material, the upper cavity being defined between the said machined surface and the membrane.

8. Electronic package according to claim 6, wherein the machined surfaces are metallized and constitute ground planes.

9. Electronic package according to claim 1, wherein it comprises means for frequency tuning the function.

10. Electronic package according to claim 9, wherein the means for frequency tuning the function consist of means for applying an electric field at the level of the function or ground planes.

11. Electronic package according to claim 1, wherein the package is made of silicon, the membrane being made of material of silica or silicon nitride type or a combination of the two, or benzocyclobutene.

12. Electronic package according to claim 11, wherein the function is of filter, delay line, phase shifter type.
